(19) United States
(12) Patent Application Publication
(10) Pub. No.: US 2026/0155760 A1
(43) Pub. Date: Jun. 4, 2026

(54) ELECTRONIC CIRCUITRY, DRIVE CIRCUIT, AND CALCULATION METHOD

(71) Applicant: Kabushiki Kaisha Toshiba, Tokyo (JP)

(72) Inventors: Takeshi UENO, Kawasaki Kanagawa (JP); Kohei HORII, Kawasaki Kanagawa (JP); Shusuke KAWAI, Fujisawa Kanagawa (JP); Hiroaki ISHIHARA, Yokohama Kanagawa (JP); Koutaro MIYAZAKI, Taito Tokyo (JP); Yuto BUSHIMATA, Kawasaki Kanagawa (JP)

(21) Appl. No.: 19/307,512

(22) Filed: Aug. 22, 2025

(30) Foreign Application Priority Data
Nov. 29, 2024 (JP) 2024-208954

(51) Int. Cl. H02M 7/5387; G01R 19/00; H02M 1/088

(52) U.S. Cl. CPC H02M 7/5387; G01R 19/0092; H02M 1/088

(57) ABSTRACT

According to one embodiment, an electronic circuitry includes: a timing detector configured to detect a voltage generated in a parasitic inductance of a switching element, the driving of the switching element being controlled in accordance with a control signal and to detect a first timing at which the voltage becomes lower or higher than a predetermined value, and a second timing, occurring after the first timing, at which the voltage becomes higher or lower than the predetermined value; and a calculator configured to calculate a slew rate of a current flowing through the switching element based on a current flowing through the switching element at the first timing and the second timing.

### CROSS REFERENCE TO RELATED APPLICATIONS

This application is based upon and claims the benefit of priority from the prior Japanese Patent Application No. 2024-208954, filed on Nov. 29, 2024, the entire contents of which are incorporated herein by reference.

### FIELD

Embodiments described herein are related to an electronic circuitry, a drive circuit, and a calculation method.

### BACKGROUND

In a switching element used for a power source circuit, an inverter, or the like, power loss becomes smaller as a transition time in turn-on or turn-off becomes shorter. However, in the turn-on or turn-off of the switching element, electro-magnetic noise (electro-magnetic interference (EMI)) occurs, and a magnitude of the EMI becomes larger as the transition time becomes shorter. That is, the power loss and the EMI are in a trade-off relationship.

In order to adjust such a trade-off, it is possible to calculate a current slew rate in the turn-on or turn-off of the switching element and control a magnitude of a drive current to be supplied to the switching element in accordance with the calculated current slew rate. As a method of calculating a current slew rate of a switching element, a method has been known in which the current slew rate is calculated based on a voltage produced in a parasitic inductance included in the switching element, and an estimation value of the parasitic inductance. However, in general, it is difficult to accurately estimate a value of the parasitic inductance, and as a result, there is a problem that the current slew rate cannot accurately be calculated.

### BRIEF DESCRIPTION OF THE DRAWINGS

FIG. 1 is a diagram illustrating a configuration of a half-bridge inverter according to a first embodiment;

FIG. 2 is a diagram illustrating voltage and current waveforms of a switching element;

FIG. 3 is a diagram illustrating a detailed configuration of a drive circuit;

FIG. 4 is a diagram illustrating a relationship between a drain current waveform of the switching element and each voltage waveform of the drive circuit;

FIG. 5 is a diagram explaining an action of a current detector;

FIG. 6 is a diagram illustrating detailed configurations of drive current suppliers;

FIG. 7 is a diagram illustrating a configuration of a half-bridge inverter according to a second embodiment; and

FIG. 8 is a diagram illustrating a configuration of a three-phase inverter according to a third embodiment.

### DETAILED DESCRIPTION

According to one embodiment, an electronic circuitry includes: a timing detector configured to detect a voltage generated in a parasitic inductance of a switching element, the driving of the switching element being controlled in accordance with a control signal, and to detect a first timing at which the voltage becomes lower or higher than a predetermined value, and a second timing, occurring after the first timing, at which the voltage becomes higher or lower than the predetermined value; and a calculator configured to calculate a slew rate of a current flowing through the switching element based on a current flowing through the switching element at the first timing and the second timing.

According to one embodiment, a drive circuit includes: a timing detector configured to detect a voltage generated in a parasitic inductance of a switching element, the driving of the switching element being controlled in accordance with a control signal, and to detect a first timing at which the voltage becomes lower or higher than a predetermined value and a second timing, occurring after the first timing, at which the voltage becomes higher or lower than the predetermined value; a calculator configured to calculate a slew rate of a current flowing through the switching element based on a current flowing through the switching element at the first timing and the second timing; and a supplier configured to supply a drive current to the switching element, the drive current being based on the slew rate of the current flowing through the switching element.

According to one embodiment, a calculation method includes: detecting a voltage generated in a parasitic inductance of a switching element, the driving of the switching element being controlled in accordance with a control signal, detecting a first timing at which the voltage becomes lower or higher than a predetermined value and a second timing, occurring after the first timing, at which the voltage becomes higher or lower than the predetermined value; and calculating a slew rate of a current flowing through the switching element based on a current flowing through the switching element at the first timing and the second timing.

The present embodiments will hereinafter be described with reference to drawings. In the drawings, the same reference characters will be given to the same or corresponding elements, and detailed descriptions thereof will appropriately be skipped.

### First Embodiment

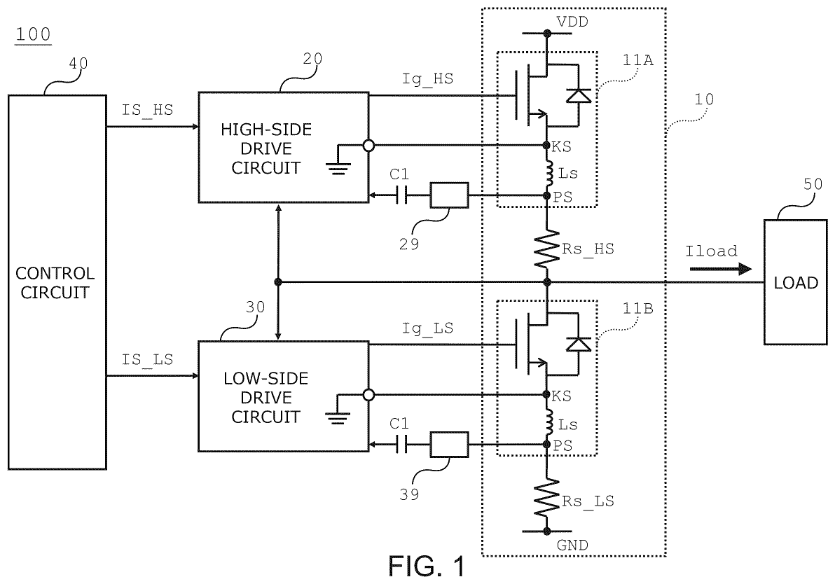

FIG. 1 is a diagram illustrating a configuration of a half-bridge inverter 100 according to a first embodiment. The half-bridge inverter 100 includes a half-bridge circuit 10, a high-side drive circuit 20, a low-side drive circuit 30, and a control circuit 40. A load 50 is connected with an output of the half-bridge inverter 100.

The half-bridge circuit 10 includes a switching element 11A on a high side and a switching element 11B on a low side, whose driving is controlled in accordance with control signals to be supplied from the control circuit 40. For example, each of the switching element 11A and the switching element 11B is an N-channel metal-oxide-semiconductor field-effect transistor (MOSFET). In this case, each of the switching element 11A and the switching element 11B has a Kelvin source terminal (KS) in addition to terminals of gate, drain, and power source (PS). Alternatively, each of the switching element 11A and the switching element 11B may be an N-channel insulated-gate bipolar transistor (IGBT). In this case, each of the switching element 11A and the switching element 11B has a Kelvin emitter terminal (KE) in addition to terminals of gate, collector, and power emitter (PE).

The drain of the switching element 11A on the high side is connected with a power source voltage VDD of the half-bridge inverter 100. The Kelvin source KS of the switching element 11A is connected with a ground of the high-side drive circuit 20. A parasitic inductance Ls (the parasitic inductance Ls on the high side) is included between the Kelvin source KS and the power source PS of the switching element 11A. The power source PS of the switching element 11A is connected with the drain of the switching element 11B on the low-side via a shunt resistor Rs_HS on the high side. A voltage of the power source PS is input to the high-side drive circuit 20 via a voltage divider circuit 29 and a capacitor C1 (the capacitor C1 on the high side).

The Kelvin source KS of the switching element 11B on the low side is connected with a ground of the low-side drive circuit 30. A parasitic inductance Ls (the parasitic inductance Ls on the low side) is included between the Kelvin source KS and the power source PS of the switching element 11B. The power source PS of the switching element 11B is connected with a ground GND of the half-bridge inverter 100 via a shunt resistor Rs_LS on the low side. The voltage of the power source PS is input to the low-side drive circuit 30 via a voltage divider circuit 39 and a capacitor C1 (the capacitor C1 on the low side).

In the present first embodiment, each of the grounds of the high-side drive circuit 20 and the low-side drive circuit 30 is separated from the ground GND of the half-bridge inverter 100. The switching element 11A and the switching element 11B, and the drive circuit 20 and the drive circuit 30 may be included in separate IC packages or may be included in the same IC package. The switching element 11A and the switching element 11B, and the drive circuit 20 and the drive circuit 30 may be mounted on different semiconductor substrates or may be mounted on the same semiconductor substrate.

As for a direction of a current (load current) Iload to be supplied from the half-bridge inverter 100 to the load 50, a direction of a flow from the half-bridge circuit 10 to the load 50 is defined as positive, and a direction of a flow from the load 50 to the half-bridge circuit 10 is defined as negative. However, those may conversely be defined.

In accordance with a high-side control signal IS_HS to be supplied from the control circuit 40, the high-side drive circuit 20 supplies a drive current Ig_HS to the switching element 11A on the high side. In detail, in a case where the high-side control signal IS_HS is “Hi” (for example, +5 V), the drive current Ig_HS flows from the drive circuit 20 to the gate of the switching element 11A. On the other hand, in a case where the high-side control signal IS_HS is “Lo” (for example, 0 V), the drive current Ig_HS flows from the gate of the switching element 11A to the drive circuit 20.

The high-side drive circuit 20 calculates, based on a voltage produced in the parasitic inductance Ls on the high side in each of turn-on and turn-off of the switching element 11A and a drain current (ON current) at a time when the switching element 11A becomes conductive, a current (current slew rate) which flows through the switching element 11A in each of the turn-on and turn-off of the switching element 11A and controls a magnitude of the drive current Ig_HS in accordance with each of the calculated current slew rates.

Similarly, in accordance with a low-side control signal IS_LS to be supplied from the control circuit 40, the low-side drive circuit 30 supplies a drive current Ig_LS to the switching element 11B on the low side. In detail, in a case where the low-side control signal IS_LS is “Hi” (for example, +5 V), the drive current Ig_LS flows from the drive circuit 30 to the gate of the switching element 11B. On the other hand, in a case where the low-side control signal IS_LS is “Lo” (for example, 0 V), the drive current Ig_LS flows from the gate of the switching element 11B to the drive circuit 30.

The low-side drive circuit 30 calculates, based on a voltage produced in the parasitic inductance Ls on the low side in each of turn-on and turn-off of the switching element 11B and the drain current (ON current) at a time when the switching element 11B becomes conductive, the current slew rate in each of the turn-on and turn-off of the switching element 11B and controls a magnitude of the drive current Ig_LS in accordance with each of the calculated current slew rates.

The control circuit 40 supplies the high-side control signal IS_HS to the high-side drive circuit 20 and supplies the low-side control signal IS_LS to the low-side drive circuit 30. The load 50 is an arbitrary electronic device or electric device which is driven by alternating-current power. For example, in a case where the load 50 is an alternating-current motor, the control circuit 40 supplies the PWM-modulated high-side control signal IS_HS to the high-side drive circuit 20 and supplies the PWM-modulated low-side control signal IS_LS to the low-side drive circuit 30. Alternatively, the half-bridge inverter 100 may be installed in power source equipment such as a PV inverter for solar photovoltaic generation. In this case, an output of the half-bridge circuit 10 is connected with an electricity network instead of the load 50.

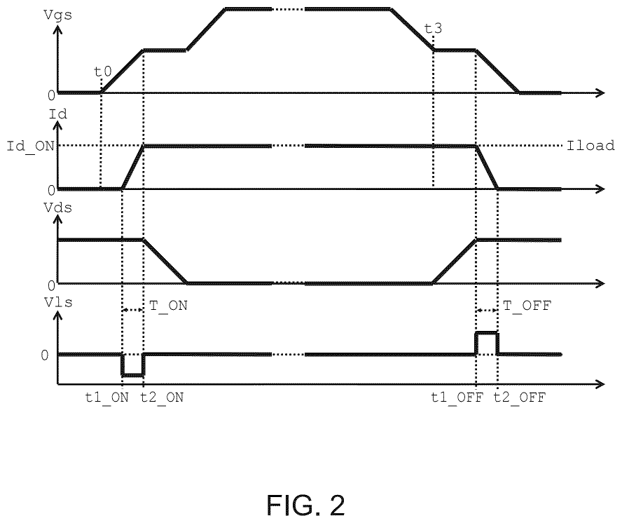

FIG. 2 is a diagram illustrating voltage and current waveforms of the switching element 11A. The highest section illustrates a time waveform of a voltage Vgs between the gate and the power source of the switching element 11A. The second section illustrates a time waveform of a drain current Id of the switching element 11A. The third section illustrates a time waveform of a voltage Vds between the drain and the power source of the switching element 11A. The lowest section illustrates a time waveform of a voltage VIs produced in the parasitic inductance Ls of the switching element 11A. Note that the same applies to voltage and current waveforms of the switching element 11B.

At a time point to, the voltage Vgs between the gate and the power source of the switching element 11A starts to rise. At a time point t1_ON, when the voltage Vgs between the gate and the power source reaches a threshold voltage, the drain current Id starts to flow. At a time point t2_ON, when the drain current Id becomes equal to the load current Iload, the rise of the drain current Id stops, and the voltage Vds between the drain and the power source starts to drop.

A period from the time point t1_ON to the time point t2_ON corresponds to a turn-on time of the switching element 11A. In a period from the time point t2_ON to a time point t1_OFF, the switching element 11A is in a conductive state, and the drain current Id in this period is an ON current Id_ON of the switching element 11A. In the present first embodiment, a current slew rate SR_ON in the turn-on of the switching element 11A is calculated in accordance with the following expression (1).

$$[ Math . 1 ]$$

$$SR\_ON = \frac{Id\_ON}{t2\_ON - t1\_ON} \qquad ( 1 )$$

When the switching element 11A is turned off, in a period from the time point t1_OFF to a time point t2_OFF, the drain current Id decreases from Id_ON to zero. The period from the time point t1_OFF to the time point t2_OFF corresponds to a turn-off time of the switching element 11A. In the present first embodiment, a current slew rate SR_OFF in the turn-off of the switching element 11A is calculated in accordance with the following expression (2).

$$[ Math . 2 ]$$

$$SR\_OFF = - \frac{Id\_ON}{t2\_OFF - t1\_OFF} \qquad ( 2 )$$

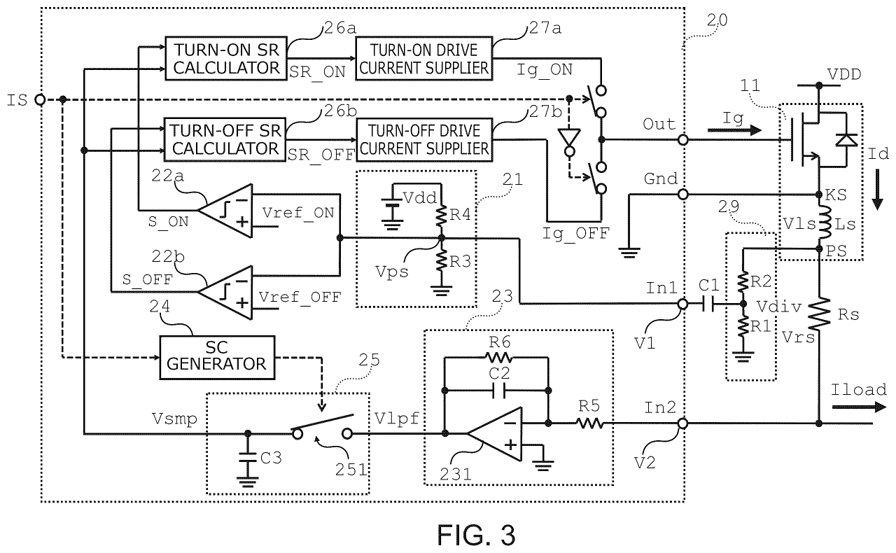

FIG. 3 is a diagram illustrating a detailed configuration of the high-side drive circuit 20. Note that a configuration of the low-side drive circuit 30 is similar to that. Hereinafter, as needed, the switching element 11A, the shunt resistor Rs_HS, and so forth will be abbreviated as a switching element 11, a shunt resistor Rs, and so forth, and subsequent descriptions will be applied to both of the high-side drive circuit 20 and the low-side drive circuit 30. The high-side drive circuit 20 and the low-side drive circuit 30 will be denoted as a drive circuit 20/30.

The drive circuit 20/30 includes a bias circuit 21, a turn-on timing detector 22a (first timing detector), a turn-off timing detector 22b (second timing detector), a low-pass filter 23, a sampling clock generator 24, a sample-hold circuit 25, a turn-on slew rate calculator 26a (first slew rate calculator), a turn-off slew rate calculator 26b (second slew rate calculator), a turn-on drive current supplier 27a, and a turn-off drive current supplier 27b.

In the present first embodiment, a voltage between the Kelvin source KS and the power source PS of the switching element 11 is equal to the voltage VIs produced in the parasitic inductance Ls of the switching element 11. The voltage VIs is divided by a resistor R1 and a resistor R2 which are included in a voltage divider circuit 29, and after a direct-current component is removed by the capacitor C1, it is input to an In1 terminal of the drive circuit 20/30. A voltage V1 to be input to the In1 terminal of the drive circuit 20/30 is expressed by the following expression (3).

$$[ Math . 3 ]$$

$${V}_{1} = \frac{R 1}{R 1 + R 2} {V}_{ls} \qquad ( 3 )$$

The bias circuit 21 includes a direct-current power source Vdd, a resistor R3, and a resistor R4 and generates a voltage Vps resulting from addition of a predetermined bias voltage Vbias to the voltage V1. The voltage Vps to be generated by the bias circuit 21 is expressed by the following expression (4).

$$[ Math . 4 ]$$

$${V}_{p s} = {V}_{1} + {V}_{bias} = \frac{R 1}{R 1 + R 2} {V}_{ls} + \frac{R 3}{R 3 + R 4} Vdd \qquad ( 4 )$$

In general, it is preferable that a voltage to be input to an integrated circuit fall between the power source voltage Vdd of the integrated circuit and a ground. In the present first embodiment, the resistors R1 to R4 and the direct-current power source Vdd are appropriately adjusted, and the voltage VIs produced in the parasitic inductance Ls of the switching element 11 is thereby converted into the voltage Vps between the power source voltage Vdd of the drive circuit 20/30 and the ground. However, in a case where the voltage VIs produced in the parasitic inductance Ls falls between the power source voltage Vdd and the ground from the beginning, the voltage divider circuit 29 and the bias circuit 21 may be omitted.

The turn-on timing detector 22a is configured with a comparator and compares the voltage Vps to be generated by the bias circuit 21 with a predetermined reference voltage Vref_ON. The turn-on timing detector 22a detects the voltage produced in the parasitic inductance Ls of the switching element 11, as the voltage Vps and compares the detected voltage with the predetermined reference voltage Vref_ON as a predetermined voltage. In detail, in a case where the voltage Vps is higher than “Vref_ON”, an output signal S_ON of the turn-on timing detector 22a becomes “Lo”. On the other hand, in a case where the voltage Vps is lower than “Vref_ON”, the output signal S_ON of the turn-on timing detector 22a becomes “Hi”.

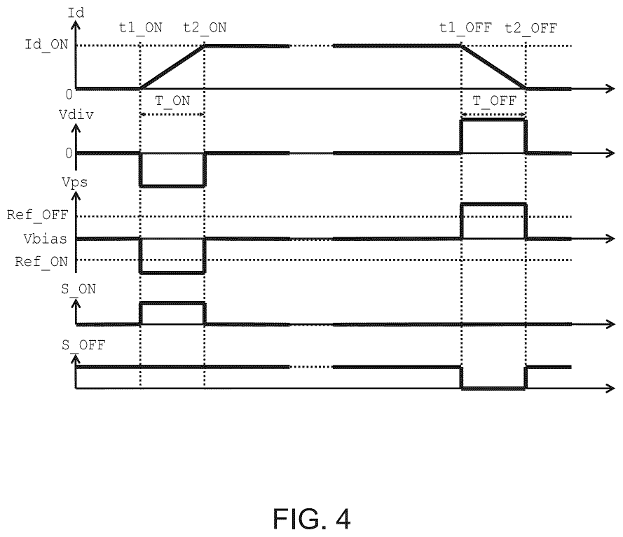

FIG. 4 is a diagram illustrating a relationship between a drain current waveform of the switching element 11 and each voltage waveform of the drive circuit 20/30. The highest section illustrates the time waveform of the drain current Id of the switching element 11. The second section illustrates a time waveform of a voltage Vdiv resulting from voltage division by the voltage divider circuit 29. The third section illustrates a time waveform of the voltage Vps to be generated by the bias circuit 21. The fourth section illustrates a time waveform of the output signal S_ON of the turn-on timing detector 22a. The lowest section illustrates a time waveform of an output signal S_OFF of the turn-off timing detector 22b.

As illustrated by the time waveform of the voltage Vps in FIG. 4, the reference voltage Vref_ON is set to a predetermined voltage value which is smaller than the bias voltage Vbias. A timing (t1_ON) when the output signal S_ON of the turn-on timing detector 22a changes from “Lo” to “Hi” corresponds to a first timing when the voltage VIs produced in the parasitic inductance Ls matches a predetermined value corresponding to the reference voltage Vref_ON. In other words, the first timing corresponds to a timing when the voltage VIs transitions from a value greater than the predetermined value to a value smaller than the predetermined value. A timing (t2_ON) when the output signal S_ON of the turn-on timing detector 22a changes from “Hi” to “Lo” corresponds to a second timing when the voltage VIs produced in the parasitic inductance Ls again matches the predetermined value corresponding to the reference voltage Vref_ON. In other words, the second timing corresponds to a timing when the voltage VIs transitions from a value smaller than the predetermined value to a value greater than the predetermined value.

The turn-on slew rate calculator 26a described later can calculate a turn-on time T_ON of the switching element 11 as t2_ON-t1_ON based on the above first timing (t1_ON) and second timing (t2_ON).

Similarly, the turn-off timing detector 22b is configured with a comparator and compares the voltage Vps to be generated by the bias circuit 21 with a predetermined reference voltage Vref_OFF. The turn-off timing detector 22b detects the voltage produced in the parasitic inductance Ls of the switching element 11, as the voltage Vps and compares the detected voltage with the predetermined reference voltage Vref_OFF as a predetermined voltage. In detail, in a case where the voltage Vps is lower than “Vref_OFF”, the output signal S_OFF of the turn-off timing detector 22b becomes “Hi”. On the other hand, in a case where the voltage Vps is higher than “Vref_OFF”, the output signal S_OFF of the turn-off timing detector 22b becomes “Lo”.

As illustrated by the time waveform of the voltage Vps in FIG. 4, the reference voltage Vref_OFF is set to a predetermined voltage value which is greater than the bias voltage Vbias. A timing (t1_OFF) when the output signal S_OFF of the turn-off timing detector 22b changes from “Hi” to “Lo” corresponds to a first timing when the voltage VIs produced in the parasitic inductance Ls matches a predetermined value corresponding to the reference voltage Vref_OFF. In other words, the first timing corresponds to a timing when the voltage VIs transitions from a value smaller than the predetermined value to a value greater than the predetermined value. A timing (t2_OFF) when the output signal S_OFF of the turn-off timing detector 22b changes from “Lo” to “Hi” corresponds to a second timing when the voltage VIs produced in the parasitic inductance Ls again matches a predetermined value corresponding to the reference voltage Vref_OFF. In other words, the second timing corresponds to a timing when the voltage VIs transitions from a value greater than the predetermined value to a value smaller than the predetermined value.

The turn-off slew rate calculator 26b described later can calculate a turn-off time T_OFF of the switching element 11 as t2_OFF-t1_OFF based on the above first timing (t1_OFF) and second timing (t2_OFF).

Note that an absolute value of the predetermined reference voltage Vref_ON and an absolute value of the predetermined reference voltage Vref_OFF may be the same value or may be different values.

Next, a voltage V2 to be input to an In2 terminal of the drive circuit 20/30 is a sum of the voltage VIs produced in the parasitic inductance Ls, and a voltage Vrs produced in the shunt resistor Rs, and is expressed by the following expression (5).

$$[ Math . 5 ]$$

$${V}_{2} = {V}_{ls} + {V}_{rs} = - \frac{d ( Id )}{dt} - Id \cdot Rs \qquad ( 5 )$$

When the switching element 11 becomes conductive, that is, in the period from the time point t2_ON to the time point t1_OFF in FIG. 2, the drain current Id is the constant ON current Id_ON which does not change over time. Consequently, the voltage V2 at a time when the switching element 11 becomes conductive is expressed by the following expression (6) by using the ON current Id_ON.

$$[ Math . 6 ]$$

$${V}_{2} = - Id\_ON \cdot Rs \qquad ( 6 )$$

However, even when the switching element 11 becomes conductive, high-frequency noise which occurs in the turn-on of the switching element 11 remains in the voltage V2. The low-pass filter 23 removes a high-frequency noise component which remains in the voltage V2 and outputs the voltage. In detail, the low-pass filter 23 includes a resistor R5, a resistor R6, a capacitor C2, and an operational amplifier 231. An output voltage VIpf of the low-pass filter 23 is expressed by the following expression (7). A term “s” denotes an operator of the Laplace transform.

$$[ Math . 7 ]$$

$${V}_{lpf} = - \frac{R 6}{R 5 ( 1 + s C 2 R 6 )} {V}_{2} \qquad ( 7 )$$

As described above, it is preferable that the voltage to be input to the integrated circuit fall between the power source voltage Vdd of the integrated circuit and the ground. In the present first embodiment, the resistor R5, the resistor R6, and the capacitor C2 are appropriately adjusted, and the output voltage VIpf of the low-pass filter 23 is thereby caused to fall between the power source voltage Vdd of the drive circuit 20/30 and the ground. In addition, due to a property of an operational amplifier with negative feedback connection (virtual ground), the voltage V2 is fixed to the ground.

The sampling clock generator 24 and the sample-hold circuit 25 constitute a current detector which detects the ON current Id_ON of the switching element 11. Based on a control signal IS, the sampling clock generator 24 generates a sampling clock for the sample-hold circuit 25, which will next be described.

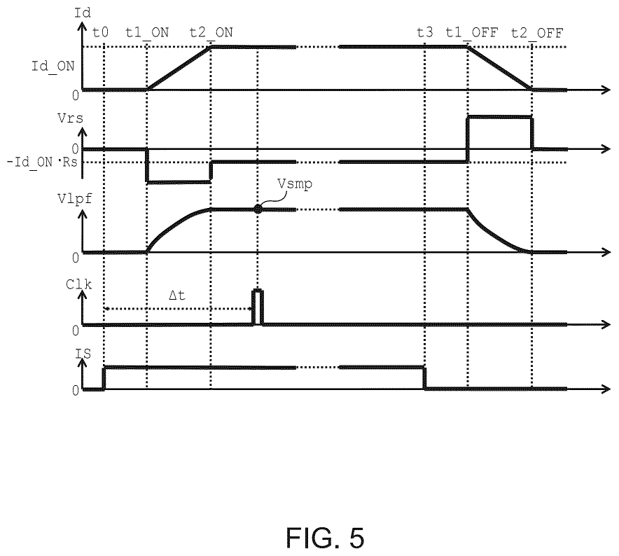

FIG. 5 is a diagram explaining an action of the current detector. The highest section illustrates the time waveform of the drain current Id of the switching element 11. The second section illustrates a time waveform of the voltage Vrs produced in the shunt resistor Rs. The third section illustrates a time waveform of the output voltage VIpf of the low-pass filter 23. The fourth section illustrates a time waveform of an output of the sampling clock generator 24. The lowest section illustrates a time waveform of the control signal IS.

As illustrated in FIG. 5, the sampling clock generator 24 outputs a clock pulse at a timing which is suitable for measuring the output voltage VIpf corresponding to the ON current Id_ON of the switching element 11. More specifically, the sampling clock generator 24 outputs the clock pulse at a timing when a predetermined time Δt has elapsed from a time point to as a reference at which the control signal rises.

The sample-hold circuit 25 samples the output voltage VIpf of the low-pass filter 23, which corresponds to the ON current Id_ON of the switching element 11. In detail, the sample-hold circuit 25 includes a capacitor C3 and a switch 251. The switch 251 is usually in an open state but becomes a closed state when the sampling clock is input, and the output voltage VIpf of the low-pass filter 23 at this point is retained in the capacitor C3.

Specifically, a voltage Vsmp to be retained by the sample-hold circuit 25 is expressed by the following expression (8).

$$[ Math . 8 ]$$

$${V}_{smp} = \frac{R 6}{R 5} Rs \cdot Id\_ON \qquad ( 8 )$$

Consequently, the ON current Id_ON of the switching element 11 is expressed by the following expression (9).

$$[ Math . 9 ]$$

$$Id\_ON = \frac{R 5}{R 6 Rs} {V}_{smp} \qquad ( 9 )$$

Note that in a case where an influence of remaining noise included in the voltage V2 is low and it is not a problem to sample the voltage V2 without any change, the low-pass filter 23 may be omitted. Because a speed of a change in the drain current Id of the switching element 11 is sufficiently slow compared to a switching frequency, a response speed of the shunt resistor Rs is not required to be high.

The turn-on slew rate calculator 26a is configured with a multiplication circuit, a central processing unit (CPU), or the like and calculates a turn-on slew rate SR_ON of the switching element 11. In detail, based on the first timing (t1_ON) and second timing (t2_ON) which are detected by the turn-on timing detector 22a and the ON current Id_ON of the switching element 11 which is detected by the current detector, the turn-on slew rate calculator 26a calculates the current slew rate SR_ON in the turn-on of the switching element 11 in accordance with the following expression (10).

$$[ Math . 10 ]$$

$$SR\_ON = \frac{Id\_ON}{t2\_ON - t1\_ON} \qquad ( 10 )$$

Similarly, the turn-off slew rate calculator 26b is configured with a multiplication circuit, a central processing unit (CPU), or the like and calculates a turn-off slew rate SR_OFF of the switching element 11. In detail, based on the first timing (t1_OFF) and second timing (t2_OFF) which are detected by the turn-off timing detector 22b and the ON current Id_ON of the switching element 11 which is detected by the current detector, the turn-off slew rate calculator 26b calculates the current slew rate SR_OFF in the turn-off of the switching element 11 in accordance with the following expression (11).

$$[ Math . 11 ]$$

$$SR\_OFF = - \frac{Id\_ON}{t2\_OFF - t1\_OFF} \qquad ( 11 )$$

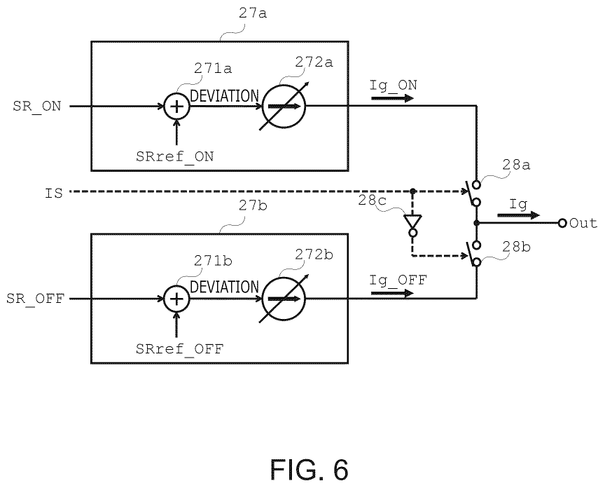

FIG. 6 is a diagram illustrating detailed configurations of the turn-on drive current supplier 27a and the turn-off drive current supplier 27b. The turn-on drive current supplier 27a includes an adder 271a and a variable current source 272a. The adder 271a calculates a deviation between the current slew rate SR_ON in the turn-on which is calculated by the turn-on slew rate calculator 26a and a predetermined target value SRref_ON. The variable current source 272a outputs a turn-on drive current Ig_ON corresponding to the deviation. Specifically, in a case where the current slew rate SR_ON in the nth turn-on is higher than the target value SRref_ON, the variable current source 272a reduces the drive current Ig_ON in the (n+1)th turn-on. For example, in a case where a drive current Ig is controlled in a digital value, the drive current Ig_ON in the (n+1)th turn-on is reduced by 1 LSB or reduced by a value corresponding to the deviation. On the other hand, in a case where the current slew rate SR_ON in the nth turn-on is lower than the target value SRref_ON, the variable current source 272a increases the drive current Ig_ON in the (n+1)th turn-on. For example, in a case where the drive current Ig is controlled in the digital value, the drive current Ig_ON in the (n+1)th turn-on is increased by 1 LSB or increased by the value corresponding to the deviation.

Similarly, the turn-off drive current supplier 27b includes an adder 271b and a variable current source 272b. The adder 271b calculates a deviation between the current slew rate SR_OFF in the turn-off which is calculated by the turn-off slew rate calculator 26b and a predetermined target value SRref_OFF. The variable current source 272b outputs a turn-off drive current Ig_OFF corresponding to the deviation.

Specifically, in a case where the current slew rate SR_OFF in the nth turn-off is higher than the target value SRref_OFF, the variable current source 272b reduces the drive current Ig_OFF in the (n+1)th turn-off. For example, in a case where the drive current Ig is controlled in the digital value, the drive current Ig_OFF in the (n+1)th turn-off is reduced by 1 LSB or reduced by the value corresponding to the deviation. On the other hand, in a case where the current slew rate SR_OFF is lower than the target value SRref_OFF, the variable current source 272b increases the drive current Ig_OFF in the (n+1)th turn-off. For example, in a case where the drive current Ig is controlled in the digital value, the drive current Ig_OFF in the (n+1)th turn-off is increased by 1 LSB or increased by the value corresponding to the deviation.

Note that as for a timing when each of the drive current suppliers 27a and 27b changes a magnitude of the drive current Ig, the magnitude of the drive current Ig may be changed as soon as possible after the nth slew rate is calculated by the slew rate calculator 26. It becomes possible to calculate the current slew rate in the turn-on at the time point t2_ON, and even when the drive current Ig is changed after the time point t2_ON, because the ON current Id_ON has already been changed, there is no influence on the current slew rate. The same applies to the current slew rate in the turn-off, and even when the drive current Ig is changed after the time point t2_OFF, there is no influence on the ON current Id_ON. Alternatively, as another method, each of the drive current suppliers 27a and 27b may refer to the control signal IS and may thereby control the variable current source 272 so as to change the magnitude of the drive current Ig at a timing of the next turn-on or turn-off.

In the turn-on of the switching element 11, that is, when the control signal IS=Hi, a switch 28a becomes a closed state, and a switch 28b becomes an open state. In this case, from an Out terminal of the drive circuit 20/30, the turn-on drive current Ig_ON which is adjusted in accordance with the current slew rate SR_ON in the previous turn-on is supplied or output as the drive current Ig. On the other hand, in the turn-off of the switching element 11, that is, when the control signal IS=Lo, because an output of a NOT gate 28c becomes “Hi”, the switch 28a becomes the open state, and the switch 28b becomes the closed state. In this case, from the Out terminal of the drive circuit 20/30, the turn-off drive current Ig_OFF which is adjusted in accordance with the current slew rate SR_OFF in the previous turn-off is supplied or output as the drive current Ig. The drive current Ig in this case becomes a current which flows in a direction from the gate of the switching element 11 to the Out terminal (drawing the current from the gate of the switching element 11).

As described above, in the present first embodiment, the slew rate calculator 26 (each of the turn-on SR calculator 26a and the turn-off SR calculator 26b) calculates a current slew rate SR of the switching element 11 based on the ON current Id_ON of the switching element 11 and the first timing (t1) and second timing (t2) when the voltage VIs produced in the parasitic inductance Ls of the switching element 11 matches the predetermined value. Consequently, when the current slew rate SR is calculated, a specific value of the parasitic inductance Ls of the switching element 11 is not necessary. By such features, in the present first embodiment, compared to related art in which the current slew rate is calculated based on an estimation value of the parasitic inductance Ls, the current slew rate of the switching element can more accurately be calculated.

In the present first embodiment, the drive current supplier 27 supplies the drive current Ig, which corresponds to the current slew rate SR calculated by the slew rate calculator 26, to the switching element 11. Accordingly, the current slew rate in the turn-on or the turn-off of the switching element can freely be adjusted. As a result, a trade-off between power loss and EMI of the switching element can be realized.

### Second Embodiment

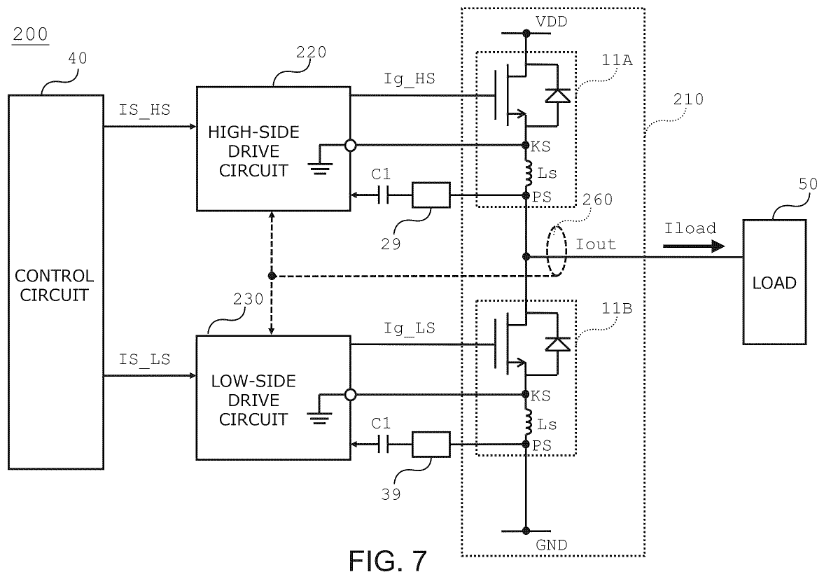

FIG. 7 is a diagram illustrating a configuration of a half-bridge inverter 200 according to a second embodiment. In the present second embodiment, the half-bridge inverter 200 includes a current sensor 260 which measures an output current Iout of a half-bridge circuit 210 instead of the shunt resistor Rs, the low-pass filters 23, the sampling clock generators 24, and the sample-hold circuits 25 of the first embodiment. For example, the current sensor 260 may be a Hall effect element.

When the high-side control signal IS_HS=Hi, the turn-on SR calculator 26a of a high-side drive circuit 220 detects the ON current Id_ON=Iout of the switching element 11A from the output current Iout of the half-bridge circuit 210 which is detected by the current sensor 260. Similarly, when the low-side control signal IS_LS=Hi, the turn-on SR calculator 26a of a low-side drive circuit 230 detects the ON current Id_ON=Iout of the switching element 11B from the output current Iout of the half-bridge circuit 210 which is detected by the current sensor 260.

In the present second embodiment, because the shunt resistor Rs is not necessary for detecting the ON current Id_ON of the switching element 11, an occurrence of power loss or noise in the shunt resistor Rs can be avoided. Because a speed of a change in the load current Iload is sufficiently slow compared to the switching frequency, a response speed of the current sensor 260 is not required to be high. Consequently, a comparatively inexpensive current sensor can be used.

### Third Embodiment

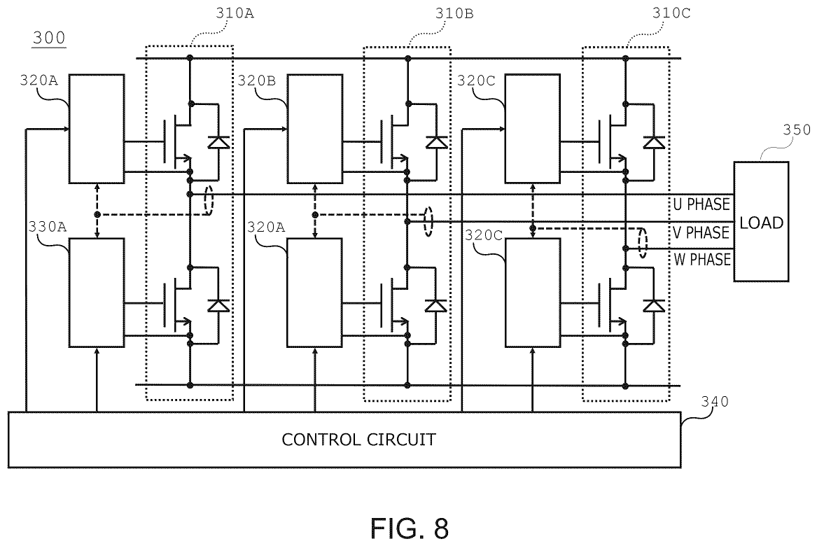

FIG. 8 is a diagram illustrating a configuration of a three-phase inverter 300 according to a third embodiment. The three-phase inverter 300 includes three half-bridge circuits 310A to 310C, three high-side drive circuits 320A to 320C, three low-side drive circuits 330A to 330C, and a control circuit 340. A load 350 is connected with an output of the three-phase inverter 300. Each of the half-bridge circuits 310A to 310C has the same configuration as the half-bridge circuit 210 of the second embodiment. Each of the high-side drive circuits 320A to 320C has the same configuration as the drive circuit 220 of the second embodiment. Each of the low-side drive circuits 330A to 330C has the same configuration as the drive circuit 230 of the second embodiment.

The control circuit 340 supplies a high-side control signal to each of the high-side drive circuits 320A to 320C and supplies a low-side control signal to each of the low-side drive circuits 330A to 330C. The load 350 is an arbitrary electronic device or electric device which is driven by three-phase alternating-current power. For example, in a case where the load 350 is a three-phase alternating-current motor, the control circuit 340 supplies the PWM-modulated high-side control signal to each of the high-side drive circuits 320A to 320C and supplies the PWM-modulated low-side control signal to each of the low-side drive circuits 330A to 330C. Note that in control of a common three-phase inverter, a current sensor for detecting a current in each phase is often needed. In this case, a current sensor does not have to be newly added for each of the drive circuits on the high side and the low side, and a current sensor which is already provided can be used.

As another application example, an inverter which includes a high-side drive circuit, a low-side drive circuit, a half-bridge circuit, and a control circuit may be used as a PV inverter for solar photovoltaic generation. In this case, an output of the PV inverter is connected with an electricity network.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Note that the present embodiments can employ the following configurations.

[Clause 1] (Electronic circuitry)

An electronic circuitry comprising:
a timing detector (22) configured to
   detect a voltage (VIs) generated in a parasitic inductance (Ls) of a switching element (11), the driving of the switching element being controlled in accordance with a control signal (IS) and
   detect a first timing (t1) at which the voltage becomes lower or higher than a predetermined value, and a second timing (t2), occurring after the first timing, at which the voltage becomes higher or lower than the predetermined value; and
a calculator (26) configured to calculate a slew rate (SR) of a current flowing through the switching element based on a current (Id_ON) flowing through the switching element at the first timing and the second timing.

### [Clause 2]

The electronic circuitry according to Clause 1, wherein
the calculator (26) configured to calculate the slew rate of the current flowing through the switching element in accordance with the following expression:

$$SR = Id\_ON / ( t 2 - t 1 )$$

where “SR” denotes the slew rate of the current flowing through the switching element, “Id_ON” denotes the current flowing through the switching element, “t1” denotes the first timing, and “t2” denotes the second timing.

### [Clause 3]

The electronic circuitry according to Clause 1 or 2, wherein
the timing detector (22) comprises:
a first timing detector (22a) configured to detect the first timing (t1_ON) and the second timing (t2_ON) during turn-on of the switching element; and
a second timing detector (22b) configured to detect the first timing (t1_OFF) and the second timing (t2_OFF) during turn-off of the switching element, and
the calculator (26) includes:
a first slew rate calculator (26a) configured to calculate the slew rate (SR_ON) during the turn-on of the switching element based on a current flowing through the switching element at the first timing (t1_ON) and the second timing (t2_ON); and
a second slew rate calculator (26b) configured to calculate the slew rate (SR_OFF) during the turn-off of the switching element based on a current flowing through the switching element at the first timing (t1_OFF) and the second timing (t2_OFF).

### [Clause 4]

The electronic circuitry according to any one of Clauses 1 to 3, further comprising
a current detector configured to detect the current flowing through the switching element based on a voltage (Vrs) generated across a shunt resistor (Rs) connected in series with the switching element, in which
the calculator uses the current detected by the current detector.

### [Clause 5]

The electronic circuitry according to any one of Clauses 1 to 3, in which
the switching element is included in a half-bridge circuit, and
the calculator uses, as the current flowing through the switching element, an output current (Iout) of the half-bridge circuit, the output current detected by a current sensor (260).

### [Clause 6]

The electronic circuitry according to Clause 4, wherein
the current detector (24, 25) comprises:
a generator (24) configured to generate a sampling clock based on the control signal (IS); and
a sample-hold circuit (25) configured to sample the current flowing through the switching element in accordance with the sampling clock.

### [Clause 7]

The electronic circuitry according to any one of Clauses 1 to 6, wherein
the switching element is a MOSFET, and
the voltage (VIs) generated in the parasitic inductance is a voltage between a Kelvin source terminal (KS) and a power source terminal (PS) of the MOSFET.

### [Clause 8]

The electronic circuitry according to any one of Clauses 1 to 6, wherein
the switching element is an IGBT, and
the voltage (VIs) generated in the parasitic inductance is a voltage between a Kelvin emitter terminal (KE) and a power emitter terminal (PE) of the IGBT.

### [Clause 9] (Drive Circuit)

A drive circuit comprising:
a timing detector (22) configured to
   detect a voltage (VIs) generated in a parasitic inductance (Ls) of a switching element (11), the driving of the switching element being controlled in accordance with a control signal (IS) and
   detect a first timing (t1) at which the voltage becomes lower or higher than a predetermined value and a second timing (t2), occurring after the first timing, at which the voltage becomes higher or lower than the predetermined value;
a calculator (26) configured to calculate a slew rate (SR) of a current flowing through the switching element based on a current (Id_ON) flowing through the switching element at the first timing and the second timing; and
a supplier (27) configured to supply a drive current to the switching element, the drive current being based on the slew rate of the current flowing through the switching element.

### [Clause 10] (Three-phase Inverter)

A three-phase inverter comprising:
first to third half-bridge circuits each including two switching elements; and
first to third drive circuits according to Clause 9, configured to respectively drive the first to third half-bridge circuits.

### [Clause 11] (Calculation Method)

A calculation method including:
detecting a voltage (VIs) generated in a parasitic inductance (Ls) of a switching element (11), the driving of the switching element being controlled in accordance with a control signal (IS);
detecting a first timing (t1) at which the voltage becomes lower or higher than a predetermined value and a second timing (t2), occurring after the first timing, at which the voltage becomes higher or lower than the predetermined value; and
calculating a slew rate (SR) of a current flowing through the switching element based on a current (Id_ON) flowing through the switching element at the first timing and the second timing.

1. An electronic circuitry comprising:
a timing detector configured to
detect a voltage generated in a parasitic inductance of a switching element, the driving of the switching element being controlled in accordance with a control signal, and
detect a first timing at which the voltage becomes lower or higher than a predetermined value, and a second timing, occurring after the first timing, at which the voltage becomes higher or lower than the predetermined value; and
a calculator configured to calculate a slew rate of a current flowing through the switching element based on a current flowing through the switching element at the first timing and the second timing.

2. The electronic circuitry according to claim 1, wherein
the calculator configured to calculate the slew rate of the current flowing through the switching element in accordance with the following expression:
$$SR = Id\_ON / ( t 2 - t 1 )$$
where “SR” denotes the slew rate of the current flowing through the switching element, “Id_ON” denotes the current flowing through the switching element, “t1” denotes the first timing, and “t2” denotes the second timing.

3. The electronic circuitry according to claim 1, wherein
the timing detector comprises:
a first timing detector configured to detect the first timing and the second timing during turn-on of the switching element; and
a second timing detector configured to detect the first timing and the second timing during turn-off of the switching element, and
the calculator includes:
a first slew rate calculator configured to calculate the slew rate during the turn-on of the switching element based on a current flowing through the switching element at the first timing and the second timing; and
a second slew rate calculator configured to calculate the slew rate during the turn-off of the switching element based on a current flowing through the switching element at the first timing and the second timing.

4. The electronic circuitry according to claim 1, further comprising
a current detector configured to detect the current flowing through the switching element based on a voltage generated across a shunt resistor connected in series with the switching element, in which
the calculator uses the current detected by the current detector.

5. The electronic circuitry according to claim 1, in which
the switching element is included in a half-bridge circuit, and
the calculator uses, as the current flowing through the switching element, an output current of the half-bridge circuit, the output current detected by a current sensor.

6. The electronic circuitry according to claim 4, wherein
the current detector comprises:
a generator configured to generate a sampling clock based on the control signal; and
a sample-hold circuit configured to sample the current flowing through the switching element in accordance with the sampling clock.

7. The electronic circuitry according to claim 1, wherein
the switching element is a MOSFET, and
the voltage generated in the parasitic inductance is a voltage between a Kelvin source terminal and a power source terminal of the MOSFET.

8. The electronic circuitry according to claim 1, wherein
the switching element is an IGBT, and
the voltage generated in the parasitic inductance is a voltage between a Kelvin emitter terminal and a power emitter terminal of the IGBT.

9. A drive circuit comprising:
a timing detector configured to
detect a voltage generated in a parasitic inductance of a switching element, the driving of the switching element being controlled in accordance with a control signal and
detect a first timing at which the voltage becomes lower or higher than a predetermined value and a second timing, occurring after the first timing, at which the voltage becomes higher or lower than the predetermined value;
a calculator configured to calculate a slew rate of a current flowing through the switching element based on a current flowing through the switching element at the first timing and the second timing; and
a supplier configured to supply a drive current to the switching element, the drive current being based on the slew rate of the current flowing through the switching element.

10. A three-phase inverter comprising:
first to third half-bridge circuits each including two switching elements; and
first to third drive circuits according to claim 9, configured to respectively drive the first to third half-bridge circuits.

11. A calculation method including:
detecting a voltage generated in a parasitic inductance of a switching element, the driving of the switching element being controlled in accordance with a control signal;
detecting a first timing at which the voltage becomes lower or higher than a predetermined value and a second timing, occurring after the first timing, at which the voltage becomes higher or lower than the predetermined value; and
calculating a slew rate of a current flowing through the switching element based on a current flowing through the switching element at the first timing and the second timing.
